(19) United States
(12) Patent Application Publication
(10) Pub. No.: US 2016/0204126 A1
(43) Pub. Date: Jul. 14, 2016

(54) THIN-FILM TRANSISTOR SUBSTRATE AND METHOD FOR FABRICATING THE SAME

(71) Applicant: JOLED INC., Chiyoda-ku, Tokyo (JP)

(72) Inventor: Kuniaki AMANO, Hyogo (JP)

(73) Assignee: JOLED INC., Tokyo (JP)

(21) Appl. No.: 14/913,464

(22) PCT Filed: May 20, 2014
(86) PCT No.: PCT/JP2014/002653

§ 371 Date: Feb. 22, 2016

(30) Foreign Application Priority Data
Aug. 27, 2013 (JP) 2013-176104

(51) Int. Cl. H01L 27/12; H01L 29/786

(52) U.S. Cl. CPC H01L 27/124; H01L 27/1259; H01L 27/1225; H01L 29/78693

(57) ABSTRACT

A TFT substrate includes: a substrate; a gate electrode above the substrate; an oxide semiconductor layer above the substrate; a gate insulating film between the gate electrode and the oxide semiconductor layer; a source electrode and a drain electrode which are connected to the oxide semiconductor layer; oxide films on the surface of the source electrode and the surface of the drain electrode, respectively; a first protective film covering the oxide films; a first interconnect layer connected to the source electrode and the drain electrode via respective first contact holes extending through the first protective film and the oxide films; wherein the source electrode and the drain electrode are each a laminated film including a Cu film and a Cu—Mn alloy film formed on the Cu film.

### TECHNICAL FIELD

The technology disclosed herein relates to a thin-film transistor substrate and a method for fabricating the same.

### BACKGROUND ART

Active matrix display devices, such as liquid crystal display devices and organic EL display devices, include a thin film transistor (TFT) substrate on which TFTs are formed as switching elements or drive elements.

Examples of the TFT structure include a bottom-gate TFT where a gate electrode is formed below a channel layer (to a substrate side), and a top-gate TFT where the gate electrode is formed above the channel layer. The channel layer of the TFT is formed of a silicon semiconductor or an oxide semiconductor, for example.

The bottom-gate TFT is broadly divided into two structures: a channel etching structure where the channel layer is etched; and a channel-etching stopper structure where a channel etching stopper is formed when forming a source electrode and a drain electrode, to reduce damage to the channel layer.

In recent years, a technology using an oxide semiconductor as a channel layer is proposed. For example, Patent Literature (PTL) 1 discloses a TFT having a channel-etching stopper structure in which a channel layer is an oxide semiconductor.

In the TFT using the oxide semiconductor as the channel layer, silicon oxide, rather than nitride, is used as a protective layer for ensuring reliability. This is because hydrogen is used to deposit nitride, which damages the oxide semiconductor.

### CITATION LIST

### Patent Literature

[PTL 1] Japanese Unexamined Patent Application Publication No. 2010-161227

### SUMMARY OF INVENTION

### Technical Problem

In large-screen display devices, a TFT substrate includes a low-resistance interconnection. In recent years, as the low-resistance interconnection, the use of a copper (Cu) wire, rather than an aluminum (Al) wire, is considered.

The technology disclosed herein has an object to obtain a TFT substrate which has desired performance.

### Solution to Problem

To achieve the above object, one aspect of a method for fabricating a TFT substrate according to the present disclosure includes: (a) forming a gate electrode above a substrate; (b) forming a gate insulating film above the substrate; (c) forming an oxide semiconductor layer above the substrate; (d) forming an electrode connected to the oxide semiconductor layer; (e) forming an oxide film on a surface of the electrode by supplying an oxygen-containing gas; (f) forming a protective film covering the oxide film, after step (e); (g) removing a portion of the protective film and a portion of the oxide film by etching, to expose the electrode; and (h) forming a first conductor film connected to the exposed electrode, wherein step (d) includes (d-i) forming a Cu film and (d-ii) forming a Cu—Mn alloy film on the Cu film.

One aspect of the TFT substrate according to the present disclosure includes a substrate; a gate electrode above the substrate; an oxide semiconductor layer above the substrate; a gate insulating film between the gate electrode and the oxide semiconductor layer; an electrode connected to the oxide semiconductor layer; an oxide film of the electrode, on a surface of the electrode; a protective film covering the oxide film of the electrode; and a first conductor film connected to the electrode via a first contact hole extending through the protective film and the oxide film of the electrode, wherein the electrode is a laminated film including a Cu film and a Cu—Mn alloy film formed on the Cu film.

### Advantageous Effects of Invention

A TFT substrate having desired performance is implemented.

### BRIEF DESCRIPTION OF DRAWINGS

FIG. 1 is a partially cut-away perspective view of an organic EL display device according to Embodiment 1.

FIG. 2 is a perspective view showing an example of pixel banks of the organic EL display device according to Embodiment 1.

FIG. 3 is an electrical circuit diagram of a configuration of a pixel circuit included in the organic EL display device according to Embodiment 1.

FIG. 4 is a schematic sectional view of a TFT substrate according to Embodiment 1.

FIG. 5A is a magnified view of a region A in FIG. 4.

FIG. 5B is a magnified view of a region B in FIG. 4.

FIG. 6A is a cross-sectional view illustrating a step of forming a gate electrode in a method for fabricating the TFT substrate according to Embodiment 1.

FIG. 6B is a cross-sectional view illustrating a step of forming a gate insulating film in the method for fabricating the TFT substrate according to Embodiment 1.

FIG. 6C is a cross-sectional view illustrating a step of forming an oxide semiconductor layer in the method for fabricating the TFT substrate according to Embodiment 1.

FIG. 6D is a sectional view illustrating a step of forming an insulating layer in the method for fabricating the TFT substrate according to Embodiment 1.

FIG. 6E is a cross-sectional view illustrating a step of forming a laminated film in the method for fabricating the TFT substrate according to Embodiment 1.

FIG. 6F is a sectional view of a step of processing the laminated film (a step of forming S-D electrodes and interconnections) in the method for fabricating the TFT substrate according to Embodiment 1.

FIG. 6G is a cross-sectional view illustrating a step of forming an oxide film (supplying oxygen) in the method for fabricating the TFT substrate according to Embodiment 1.

FIG. 6H is a sectional view illustrating a step of forming a first protective film in the method for fabricating the TFT substrate according to Embodiment 1.

FIG. 6I is a cross-sectional view illustrating a step of forming contact holes in the method for fabricating the TFT substrate according to Embodiment 1.

FIG. 6J is a cross-sectional view illustrating a step of forming an ITO film in the method for fabricating the TFT substrate according to Embodiment 1.

FIG. 6K is a cross-sectional view illustrating a step of forming a Cu film in the method for fabricating the TFT substrate according to Embodiment 1.

FIG. 6L is a sectional view of a step of forming a second protective film in the method for fabricating the TFT substrate according to Embodiment 1.

FIG. 7 is a schematic sectional view of a TFT substrate according to Embodiment 2.

FIG. 8A is a diagram showing contact resistance of three kinds of samples, No1, No2, and No3 in a first contact hole (for a drain electrode and a top layer interconnection or for a source electrode and a top layer interconnection).

FIG. 8B is a diagram showing contact resistance of three kinds of samples, No4, No5, and No6 in a second contact hole (for a bottom layer interconnection and an extraction electrode).

FIG. 9 is a table showing characteristics of the source electrode, the drain electrode, and the bottom layer interconnection, according to their film structure and film material.

FIG. 10 is a diagram showing a relationship between a heating temperature and resistivity of the source electrode and the drain electrode.

FIG. 11 is a diagram showing a relationship between a thickness of a top layer and resistivity of the source electrode and the drain electrode.

### DESCRIPTION OF EMBODIMENTS

Hereinafter, embodiments of a thin-film transistor substrate, a method for fabricating the same, and an organic EL display device using the thin-film transistor substrate according to the present invention are to be described, with reference to the accompanying drawings. The embodiments described below are each merely illustration of the present invention. Thus, values, shapes, materials, components, and arrangement and connection between the components, steps, and the order of the steps shown in the following embodiments are merely illustrative and not intended to limit the present invention. Therefore, among the components in the embodiments below, components not recited in any one of the independent claims indicating the top level concept of the present invention are described as arbitrary components.

Figures are schematic views and do not necessarily illustrate the present invention precisely. In the figures, the same reference signs are used to refer to substantially the same configuration, and thus duplicate description is omitted or simplified.

### Embodiment 1

In the following, Embodiment 1 is described.

[Organic EL Display Device]

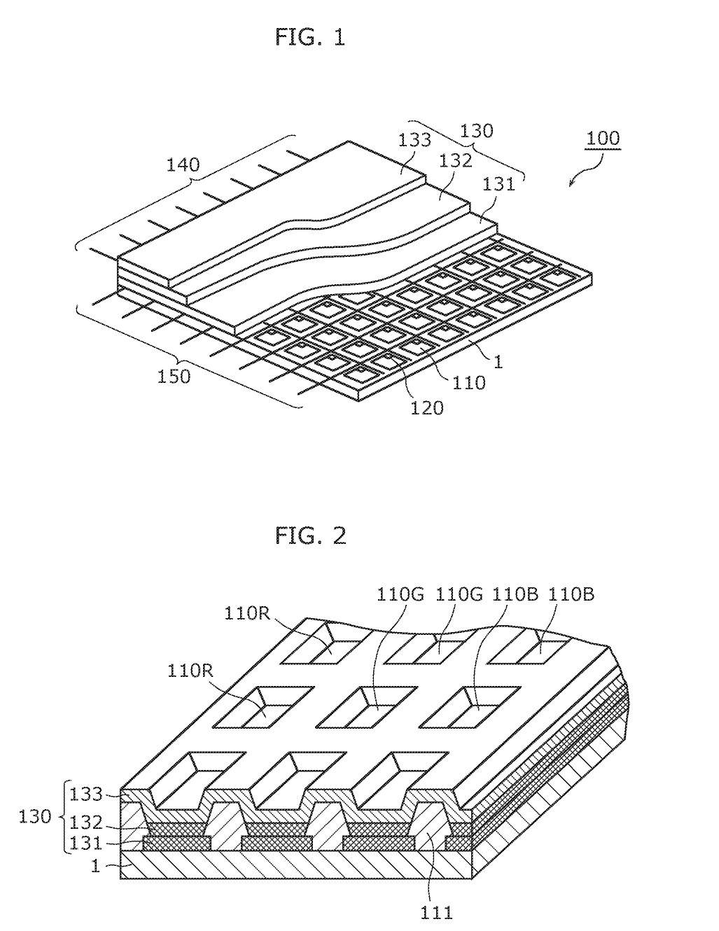

First, a configuration of an organic EL display device 100 according to Embodiment 1 is described, with reference to FIGS. 1 and 2. FIG. 1 is a partially cut-away perspective view of the organic EL display device according to Embodiment 1. FIG. 2 is a perspective view showing an example of pixel banks of the organic EL display device according to Embodiment 1.

As shown in FIG. 1, the organic EL display device 100 has a layered structure including a TFT substrate (a TFT array substrate) 1 on which a plurality of thin film transistors are disposed, and an organic EL element (a light emitting portion) 130. The organic EL element 130 includes anodes 131 which are bottom electrodes, EL layers 132 which are light emitting layers each comprising an organic material, and a cathode 133 which is a transparent top electrode.

A plurality of pixels 110 are disposed in a matrix on the TFT substrate 1, where a pixel circuit 120 is provided per pixel 110.

The organic EL element 130 is formed in one-to-one correspondence with each pixel 110. The pixel circuits 120, each provided per pixel 110, control light emission by the organic EL element 130. The organic EL element 130 is formed on an interlayer insulating film (a planarizing film) which is formed covering the plurality of thin film transistors.

The organic EL element 130 includes the EL layers 132 disposed between the anodes 131 and the cathode 133. In addition, hole-transport layers are layered between the anodes 131 and the EL layers 132, and electron-transport layers are layered between the EL layers 132 and the cathode 133. It should be noted that any other charge functional layers may be disposed between the anodes 131 and the cathode 133.

The pixels 110 are actuated by respective pixel circuits 120. On the TFT substrate 1, a plurality of gate lines (scanning lines) 140 are formed along a row direction of the pixels 110, a plurality of source lines (signal lines) 150 are formed along a column direction of the pixels 110, intersecting the gate lines 140, and a plurality of power supply lines (not shown in FIG. 1) are formed parallel with the source lines 150. Pixels 110 are partitioned by, for example, the gate lines 140 and the source lines 150 orthogonal to each other.

The gate lines 140 and gate electrodes of the thin film transistors included in the pixel circuits 120 are connected row by row. The gate electrodes act as switching elements. The source lines 150 and source electrodes of the thin film transistors included in the pixel circuits 120 are connected column by column. The source electrodes act as switching elements. The power supply lines and drain electrodes of the thin film transistors included in the pixel circuits 120 are connected column by column. The drain electrodes act as drive elements.

As shown in FIG. 2, the pixels 110 included in the organic EL display device 100 each consist of sub-pixels 110R, 110G, and 110B which emit respective three colors (red, green, blue). The plurality of sub-pixels 110R, 110G, and 110B are formed, arranged in a matrix, on a display surface of the organic EL display device 100.

The sub-pixels 110R, 110G, and 110B are separated from one another by banks 111. The banks 111 are formed in a grid such that ridges extending in parallel with the gate lines 140 intersect ridges extending in parallel with the source lines 150. Portions (i.e., an opening of each bank 111) enclosed by the ridges and the sub-pixels 110R, 110G, and 110B are in one-to-one correspondence. In the present embodiment, the banks 111 are pixel banks. The banks 111, however, may be line banks.

The anodes 131 are formed at positions on the interlayer insulating film (the planarizing film) on the TFT substrate 1 and inside the respective openings of the banks 111 for the sub-pixels 110R, 110G, and 110B. Likewise, the EL layers 132 are formed at positions on the anodes 131 and inside the respective openings of the banks 111 for the sub-pixels 110R, 110G, and 110B. The transparent cathode 133 is formed continuously across the banks 111, covering all the EL layers 132 (all the sub-pixels 110R, 110G, and 110B).

The pixel circuit 120 is provided for each of the sub-pixels 110R, 110G, and 110B. Each of the sub-pixels 110R, 110G, and 110B and a corresponding pixel circuit 120 are electrically connected to each other by a contact hole and a relay electrode. It should be noted that the sub-pixels 110R, 110G, and 110B have the same configuration, except that the EL layers 132 of the sub-pixels 110R, 110G, and 110B emit three different light beams having three different colors.

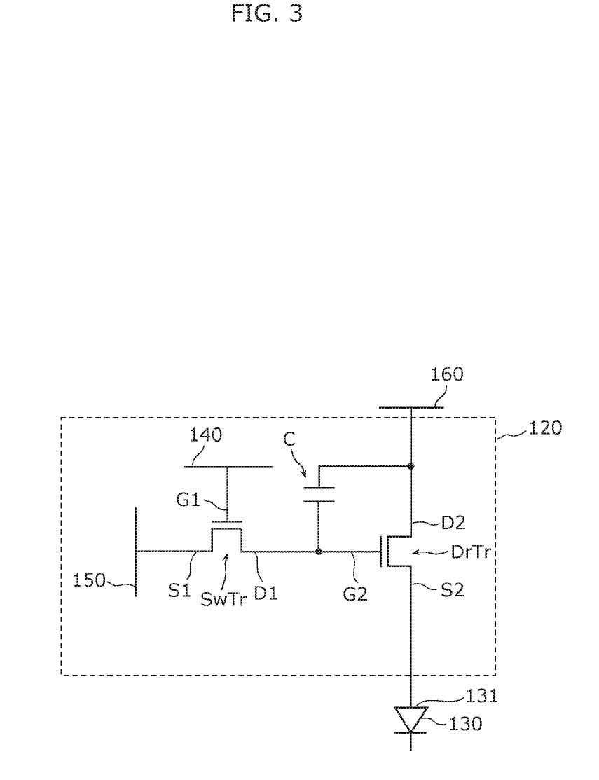

Here, a circuit structure of the pixel circuit 120 in the pixel 110 is described, with reference to FIG. 3. FIG. 3 is an electrical circuit diagram of a configuration of the pixel circuits in the organic EL display device according to Embodiment 1.

As shown in FIG. 3, the pixel circuits 120 each include a thin film transistor SwTr which acts as a switching element, a thin film transistor DrTr which acts as a drive element, and a capacitor C which stores data to be displayed by a corresponding pixel 110. In the present embodiment, the thin film transistor SwTr is a switching transistor for selecting the pixel 110, and the thin film transistor DrTr is a drive transistor for driving the organic EL element 130.

The thin film transistor SwTr includes a gate electrode G1 connected to the gate line 140, a source electrode S1 connected to the source line 150, a drain electrode D1 connected to the capacitor C and a gate electrode G2 of the thin film transistor DrTr, and a semiconductor film (not shown). If a predetermined voltage is applied to the gate line 140 and the source line 150 which are connected to the thin film transistor SwTr, a voltage applied to the source line 150 is stored as a data voltage into the capacitor C.

The thin film transistor DrTr includes the gate electrode G2 connected to the drain electrode D1 of the thin film transistor SwTr and the capacitor C, a drain electrode D2 connected to a power supply line 160 and the capacitor C, a source electrode S2 connected to the anode 131 of the organic EL element 130, and the semiconductor film (not shown). The thin film transistor DrTr sends, to the anode 131 of the organic EL element 130 through the source electrode S2, a current supplied from the power supply line 160 and corresponding to the data voltage stored in the capacitor C. This causes a drive current to flow through the organic EL element 130 from the anode 131 to the cathode 133, thereby causing the EL layer 132 to emit light.

It should be noted that the organic EL display device 100 configured as described above is an active matrix display device which controls display for each pixel 110 located at an intersection of the gate line 140 and the source line 150. This selectively causes organic EL elements 130 to emit light in response to corresponding thin film transistors SwTr and DrTr of pixels 110 (the sub-pixels 110R, 110G, and 110B), thereby displaying desired images.

[Thin-Film Transistor Substrate]

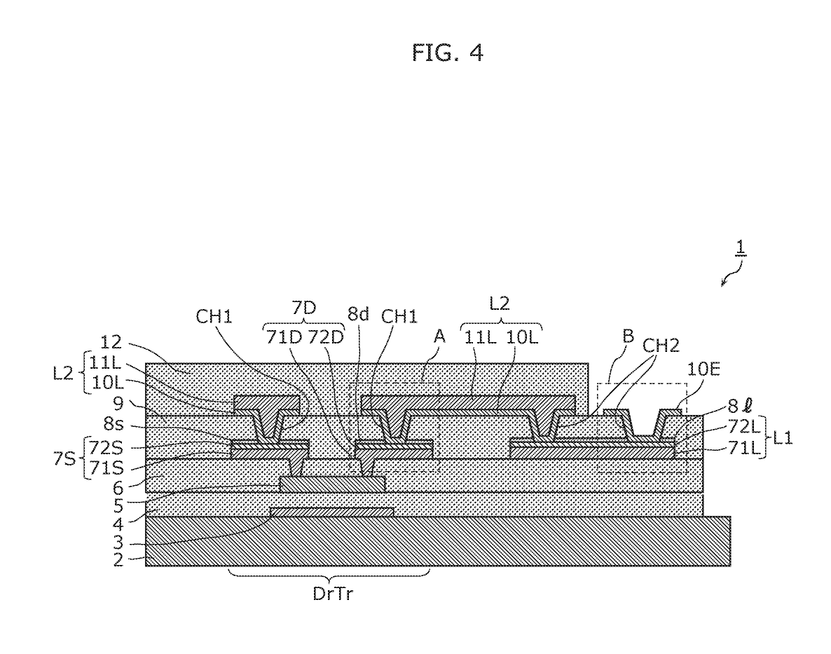

Next, the TFF substrate according to Embodiment 1 is described, with reference to FIG. 4. FIG. 4 is a schematic sectional view of the TFT substrate according to Embodiment 1. In the following embodiment, the TFT substrate 1 included in the above-described organic EL display device 100 is described. While the thin film transistor DrTr is to be described, the configuration of the thin film transistor DrTr is applicable to the thin film transistor SwTr as well. In other words, the thin film transistor described below is applicable to both the switching transistor and the drive transistor.

As shown in FIG. 4, in the TFT substrate 1, the thin film transistor DrTr is formed. The TFT substrate 1 includes a substrate 2, gate electrodes 3, a gate insulating film 4, oxide semiconductor layers 5, an insulating layer 6, source electrodes 7S, drain electrodes 7D, oxide films 8s, 8d, and 8l, a first protective film 9, bottom layer interconnections L1, top layer interconnections L2, extraction terminal electrodes 10E, and a second protective film 12.

In the TFT substrate 1, the thin film transistors DrTr each include the gate electrode 3, the gate insulating film 4, the oxide semiconductor layer 5, the insulating layer 6, the source electrode 7S, the drain electrode 7D, and the oxide films 8s and 8d. The gate electrode 3, the source electrode 7S, and the drain electrode 7D correspond to the gate electrode G2, the source electrode S2, and the drain electrode D2, respectively, in FIG. 3. The thin film transistor DrTr according to the present embodiment is a bottom-gate TFT.

The bottom layer interconnections L1 and the top layer interconnections L2 are extraction electrodes and connect the electrodes of the thin film transistors DrTr and SwTr, the various signal lines such as the gate lines 140, the source lines 150, and the power supply lines 160, and the electrodes of the organic EL element 130, for example. It should be noted that the bottom layer interconnections L1 and the top layer interconnections L2 can themselves be the various signal lines which are the gate lines 140, the source lines 150, and the power supply lines 160.

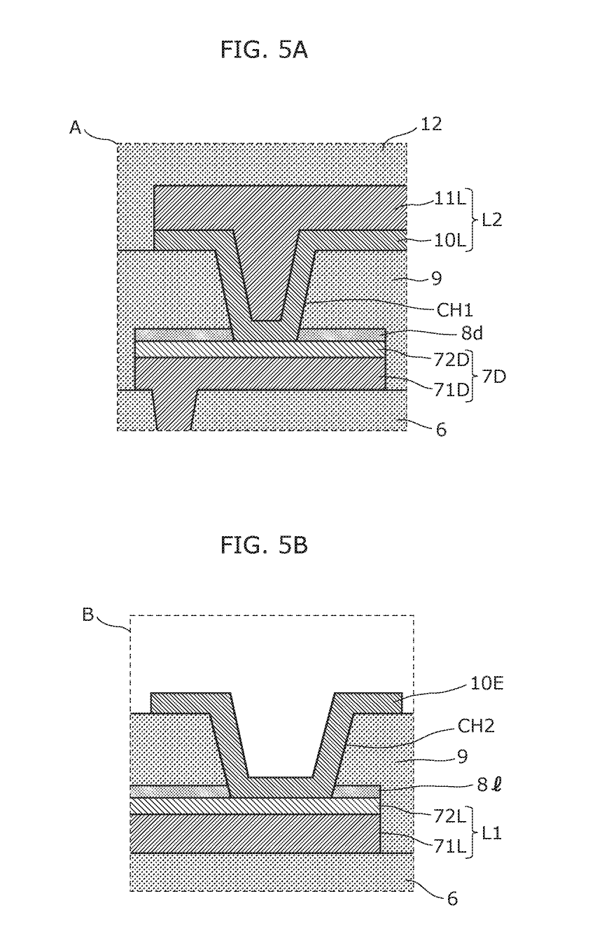

In the following, the components included in the TFT substrate 1 are described in detail, with reference to FIGS. 5A and 5B, referring to FIG. 4. FIG. 5A is a magnified view of a region A enclosed by a dashed line in FIG. 4. FIG. 5B is a magnified view of a region B enclosed by a dashed line in FIG. 4.

The substrate 2 is, for example, a glass substrate. If the thin film transistor DrTr is used for a flexible display, the substrate 2 may be a flexible substrate such as a resin substrate. It should be noted that an undercoat layer may be formed on the surface of the substrate 2.

The gate electrode 3 is formed in a predetermined shape above the substrate 2. Examples of the gate electrode 3 include metals such as Ti, Mo, W, Al, and Au, and conductive oxide such as indium tin oxide (ITO). Regarding the metal, an alloy such as MoW may be used for the gate electrode 3, for example. Alternatively, to enhance adhesion to the gate insulating film 4, for example, Ti, Al, and Au may be used as metals having good adhesion to oxide, and a laminate in which these metals are layered may be used as the gate electrode 3.

The gate insulating film 4 is formed between the gate electrode 3 and the oxide semiconductor layer 5. The gate insulating film 4 is formed on the substrate 2, covering the gate electrode 3. The gate insulating film 4 is, for example, an oxide thin film such as silicon oxide and hafnium oxide, a nitride film such as silicon nitride, or a monolayer film of silicon oxynitride, or a laminated film of these films.

The oxide semiconductor layer 5 is formed in a predetermined shape above the substrate 2. The oxide semiconductor layer 5 is a channel layer (a semiconductor layer) of the thin film transistor DrTr and formed so as to overlap with the gate electrode 3 in plan view. For example, the oxide semiconductor layer 5 is formed in an island form on the gate insulating film 4 and above the gate electrode 3.

Desirably, the oxide semiconductor layer 5 is formed of a transparent amorphous oxide semiconductor (TAOS) such as InGaZnO_{X} (IGZO) containing In—Ga—Zn—O. The ratio of In:Ga:Zn may be, approximately, 1:1:1, for example. Alternatively, the ratio of In:Ga:Zn may be, but not limited to, in a range of 0.8 to 1.2:0.8 to 1.2:0.8 to 1.2. A thin film transistor which includes the transparent amorphous oxide semiconductor as the channel layer has high carrier mobility, and is suitable for large, high-resolution screens of display devices. In addition, since the transparent amorphous oxide semiconductor can be deposited by a low temperature deposition, the transparent amorphous oxide semiconductor can readily be formed on a flexible substrate such as a plastic or a film.

The transparent amorphous oxide semiconductor expressed by InGaZnO_{X} can be deposited by a vapor deposition such as a sputtering technique or a laser deposition technique, using, as a target, a polycrystalline sintered body having a composition of InGaO₃(ZnO)₄, for example.

Preferably, the oxide semiconductor layer 5 has a thickness of at least 10 nm to at least 150 nm. If the thickness is less than 10 nm, pinholes are likely to occur. If the thickness is greater than 150 nm, a leakage current and a subthreshold swing value (S value) increase and the transistor properties degrade during the off operation of the thin film transistor DrTr.

Also preferably, in the oxide semiconductor layer 5, atomic concentration of Cu in a channel region between the source electrode 7S and the drain electrode 7D is 1×10⁻¹⁹/cm³ or less. If the atomic concentration (an amount of contamination) of Cu is great, the leakage current increases, causing variations in transistor properties and increasing power consumption by the thin film transistor DrTr.

It should be noted that the atomic concentration (an amount of contamination) of Cu can be assessed by secondary ion mass spectroscopy (SIMS), that is, by irradiating a specimen surface with ions (primary ions) and mass analyzing ions (secondary ions) among particles came out in response to the irradiation, thereby assessing qualitative or quantitative measurements on components included in a sample.

The insulating layer 6 is deposited on the gate insulating film 4, covering the oxide semiconductor layer 5. Specifically, the oxide semiconductor layer 5 is covered with the insulating layer 6 and the insulating layer 6 serves as a protective layer (a channel protection layer) which protects the oxide semiconductor layer 5. One example of the insulating layer 6 is a silicon oxide (SiO₂) film. Portions of the insulating layer 6 are opened extending therethrough and the oxide semiconductor layer 5 is connected to the source electrode 7S and the drain electrode 7D via the open portions (contact holes).

The source electrode 7S and the drain electrode 7D are formed in predetermined shapes on the insulating layer 6. Specifically, the source electrode 7S and the drain electrode 7D are connected to the oxide semiconductor layer 5 via the contact holes in the insulating layer 6, and disposed, on the insulating layer 6, facing each other at a predetermined space apart in the horizontal direction of the substrate 2.

The source electrode 7S and the drain electrode 7D are each made of a material comprising Cu. Specifically, the source electrode 7S is a laminated film including a first electrode film 71S which is a Cu (copper) film, and a second electrode film 72S which is a copper manganese (Cu—Mn) alloy film formed on the first electrode film 71S. Likewise, the drain electrode 7D is a laminated film including a first electrode film 71D which is a Cu film, and a second electrode film 72D which is a Cu—Mn alloy film formed on the first electrode film 71D. It should be noted that the Cu—Mn alloy film refers to a film comprising an alloy of copper and manganese.

The first electrode films 715 and 71D are primary electrode layers of the source electrode 7S and the drain electrode 7D, respectively. In the present embodiment, the first electrode films 71S and 71D are bottom electrode layers to be the lowermost layers of the source electrode 7S and the drain electrode 7D, respectively, and are formed on the insulating layer 6. The first electrode films 71S and 72D are connected to the oxide semiconductor layer 5 via the open portions of the insulating layer 6. The use of the Cu films as the first electrode films 71S and 71D can reduce the resistance of the first electrode films 71S and 71D.

The second electrode films 72S and 72D are cap layers for protecting the respective primary electrode layers, and layered on the first electrode films 71S and 71D, respectively. In the present embodiment, the second electrode films 72S and 72D are top electrode layers which are the uppermost layers of the source electrode 7S and the drain electrode 7D. The use of the Cu—Mn alloy films as the second electrode films 72S and 72D oxidizes Cu atoms of the first electrode films 71S and 71D, respectively, thereby suppressing the first electrode films 71S and 71D from altering. This can suppress the source electrode 7S and the drain electrode 7D from increasing their resistance due to the oxidization of Cu.

While in the present embodiment, the insulating layer 6 is disposed between the oxide semiconductor layer 5 and the source electrode 7S and between the oxide semiconductor layer 5 and the drain electrode 7D, it should be noted that the source electrode 7S and the drain electrode 7D may be formed directly covering the end portions of the oxide semiconductor layer 5, without the insulating layer. The source electrode 7S and the drain electrode 7D may at least be electrically connected to the oxide semiconductor layer 5 so that carriers can move.

The bottom layer interconnection L1 is also formed on the insulating layer 6. The bottom layer interconnection L1 is a first interconnection formed in the same layer as the source electrode 7S and the drain electrode 7D, and includes a first interconnect layer 71L and a second interconnect layer 72L layered on the first interconnect layer 71L. In other words, the bottom layer interconnection L1 has the same film structure as the source electrode 7S and the drain electrode 7D, and is a laminated film including the Cu film and the Cu—Mn alloy film.

The first interconnect layer 71L is a bottom interconnect layer which is the lowermost layer of the bottom layer interconnection L1. The first interconnect layer 71L is the same Cu film as the first electrode films 71S and 71D. Use of Cu as an interconnect material of the first interconnect layer 71L can reduce the resistance of the bottom layer interconnection L1. This can implement a low-resistance interconnection.

The second interconnect layer 72L is a top interconnect layer which is the uppermost layer of the bottom layer interconnection L1. The second interconnect layer 72L is the same Cu—Mn alloy film as the second electrode films 72S and 72D. The second interconnect layer 72L is a cap layer for protecting the first interconnect layer 71L, and the use of CuMn as an interconnect material of the second interconnect layer 72L oxidizes Cu atoms of the first interconnect layer 71L, thereby suppressing the first interconnect layer 71L from altering. This can suppress the bottom layer interconnection L1 from increasing resistance due to the oxidization of Cu.

The bottom layer interconnection L1 configured as such also serves as an interconnection which supplies the various signals (voltages) as described above. A portion of the top layer interconnection L2 not covered with the second protective film 12 is an extraction electrode (an external connection terminal) extracted to a peripheral edge of the TFT substrate 1 to establish electrical connection between the TFT substrate 1 and an external device. A predetermined electric signal is input to the TFT substrate 1 from the extraction electrode.

The oxide film 8s and the oxide film 8d are surface oxide films (surface oxide layers) formed by oxidizing the source electrode 7S and the drain electrode 7D, respectively. The oxide film 8s and the oxide film 8d are formed on the surface of the source electrode 7S and the surface of the drain electrode 7D, respectively. Specifically, the oxide films 8s and 8d are oxide films (e.g., manganese oxide: MnOₓ) formed by respectively oxidizing the second electrode films 72S and 72D which are the Cu—Mn alloy films, and formed on the respective surfaces of the second electrode films 72S and 72D.

Portions of the oxide films 8s and 8d corresponding to first contact holes CH1 are removed. Specifically, the portions of the oxide films 8s and 8d are removed by etching for forming the first contact holes CH1. In other words, the oxide films 8s and 8d are formed on the surfaces of the second electrode films 72S and 72D, respectively, except for the portions where the first contact holes CH1 are formed.

In the present embodiment, the oxide film 8l is formed on the surface of the bottom layer interconnection L1. The oxide film 8l is a surface oxide film (a surface oxide layer) formed by oxidizing the bottom layer interconnection L1. Specifically, the oxide film 8l is an oxide film (e.g., manganese oxide: MnOₓ) formed by oxidizing the second interconnect layer 72L which is the Cu—Mn alloy film. The oxide film 8l is formed on the surface of the second interconnect layer 72L.

Portions of the oxide film 8l corresponding to second contact holes CH2 are removed. Specifically, the portions of the oxide film 81 are removed by etching for forming the second contact holes CH2. In other words, the oxide film 8l is formed on the surface of the bottom layer interconnection L1, except for the portions where the second contact holes CH2 are formed.

The first protective film 9 is an insulating layer and formed on the insulating layer 6, covering the source electrode 7S and the drain electrode 7D. The first protective film 9 is formed covering also the bottom layer interconnection L1. Specifically, the source electrode 7S, the drain electrode 7D, and the bottom layer interconnection L1 are covered with the first protective film 9, and the first protective film 9 serves as a protective layer for protecting the source electrode 7S, the drain electrode 7D, and the bottom layer interconnection L1. One example of the first protective film 9 is a silicon oxide (SiO₂) film.

In the present embodiment, since the oxide films 8s, 8d, and 8l are formed on the respective surfaces of the source electrode 7S, the drain electrode 7D, and the bottom layer interconnection L1, the first protective film 9 is formed also on the oxide films 8s, 8d, and 8l.

Portions of the first protective film 9 are opened extending therethrough. Via the open portions (the first contact holes CH1 and the second contact hole CH2), the source electrode 7S and the drain electrode 7D are connected to the top layer interconnection L2, and the bottom layer interconnection L1 is connected to the top layer interconnection L2.

It should be noted that the first contact holes CH1 are formed extending not only through the first protective film 9 but also through the oxide films 8s and 8d. Also, the second contact holes CH2 are formed extending not only through the first protective film 9 but also through the oxide film 8l.

The top layer interconnection L2 is formed in a predetermined shape on the first protective film 9. The top layer interconnection L2 is connected to the source electrode 75 and the drain electrode 7D via the first contact holes CH1 extending through the first protective film 9 and the oxide films 8s and 8d. The top layer interconnection L2 is also connected to the bottom layer interconnection L1 via the second contact hole CH2 extending through the first protective film 9 and the oxide film 8l.

In the present embodiment, the top layer interconnection L2 includes a first interconnect layer 10L and a second interconnect layer 11L.

The first interconnect layer 10L is formed on the first protective film 9. The first interconnect layer 10L is a bottom interconnect layer which is the lowermost layer of the top layer interconnection L2. The first interconnect layer 10L is a first conductor film connected to the source electrode 7S and the drain electrode 7D via the first contact holes CH1. In the present embodiment, the first interconnect layer 10L is also connected to the bottom layer interconnection L1 via the second contact hole CH2.

Specifically, the first interconnect layer 10L is formed on the first protective film 9 and along the inner surfaces of the first contact holes CH1 and the second contact holes CH2. The first interconnect layer 10L comprises transparent conductive oxide. The first interconnect layer 10L (the first conductor film) according to the present embodiment is an ITO film.

The second interconnect layer 11L is formed on the first interconnect layer 10L. The second interconnect layer 11L is a top interconnect layer which is the uppermost layer of the top layer interconnection L2.

Specifically, the second interconnect layer 11L is formed, on the first interconnect layer 10L, filling the first contact holes CH1 and the second contact holes CH2. The second interconnect layer 11L comprises low resistance metal. The second interconnect layer 11L according to the present embodiment is the Cu film.

The extraction terminal electrode 10E protects the top layer interconnection L2 serving as the extraction electrode. The extraction terminal electrode 10E and the top layer interconnection L2 constitute the extraction electrode (the external connection terminal). Providing the extraction terminal electrode 10E can inhibit deterioration of the extraction electrode (the bottom layer interconnection L1) due to a subsequent etching process, for example.

The extraction terminal electrode 10E is a second conductor film connected to the bottom layer interconnection L1 through the second contact hole CH2. The extraction terminal electrode 10E is formed along the inner surface of the second contact hole CH2.

The extraction terminal electrode 10E and the first interconnect layer 10L are formed in the same layer. Specifically, the extraction terminal electrode 10E comprises the same material as the first interconnect layer 10L included in the top layer interconnection L2. The extraction terminal electrode 10E is formed using the transparent conductive oxide. The extraction terminal electrode 10E (the second conductor film) according to the present embodiment is the ITO film.

It should be noted that the extraction terminal electrode 10E is not covered with the second protective film 12, and exposed.

The second protective film 12 is an insulating layer and formed on the first protective film 9, covering the top layer interconnection L2. Specifically, the second protective film 12 covers the top layer interconnection L2, and serves as a protective layer for protecting the top layer interconnection L2. The second protective film 12 also has a function of insulation for the top layer interconnection L2 against an electrode of an organic EL element (the light emitting layer) formed on a top layer of the TFT substrate 1. Although not shown, a contact hole is formed in the second protective film 12. Through the contact hole, the source electrode 7S or the drain electrode 7D is connected via the top layer interconnection L2 or directly to the electrode (e.g., the anode) of the organic EL element formed on the top layer.

The second protective film 12 comprises a resin-coated photosensitive insulating material including silsesquioxane, acrylic, and siloxane, which can attenuate light that has a wavelength of 450 nm or less, for example. The second protective film 12 may be a laminated film comprising the photosensitive insulating material and an inorganic insulating material, or may be a monolayer film comprising the inorganic insulating material. Examples of the inorganic insulating material include silicon oxide, aluminum oxide, and titanium oxide. The inorganic insulating material is deposited by CVD, sputtering, or ALD, for example.

[Method for Fabricating Thin-Film Transistor Substrate]

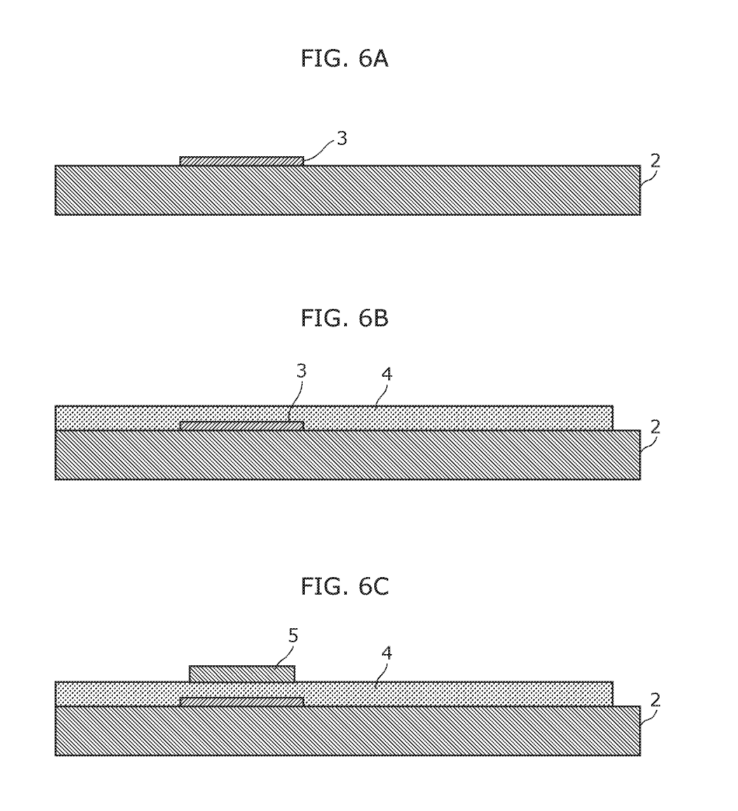

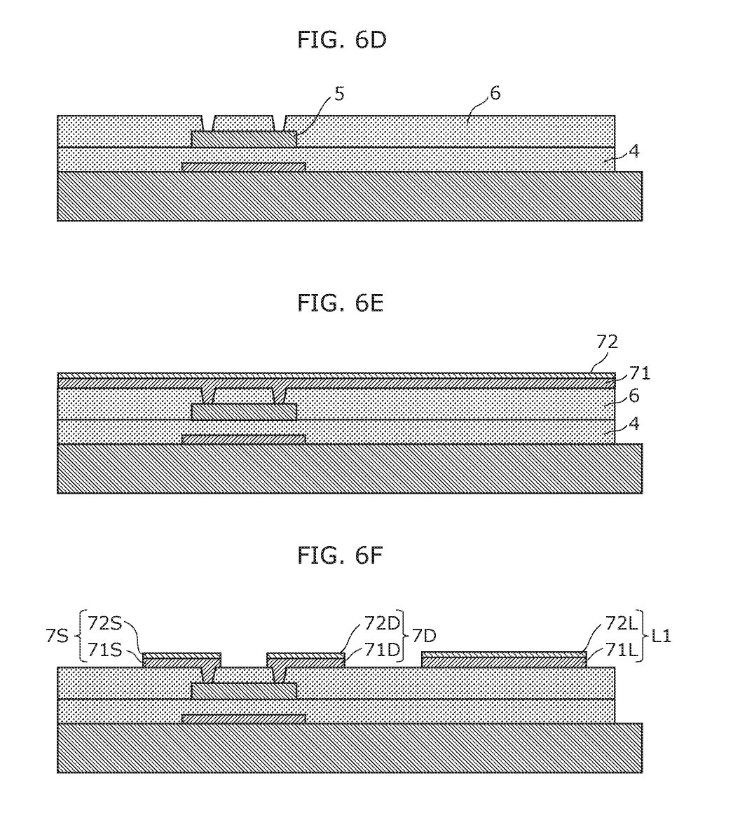

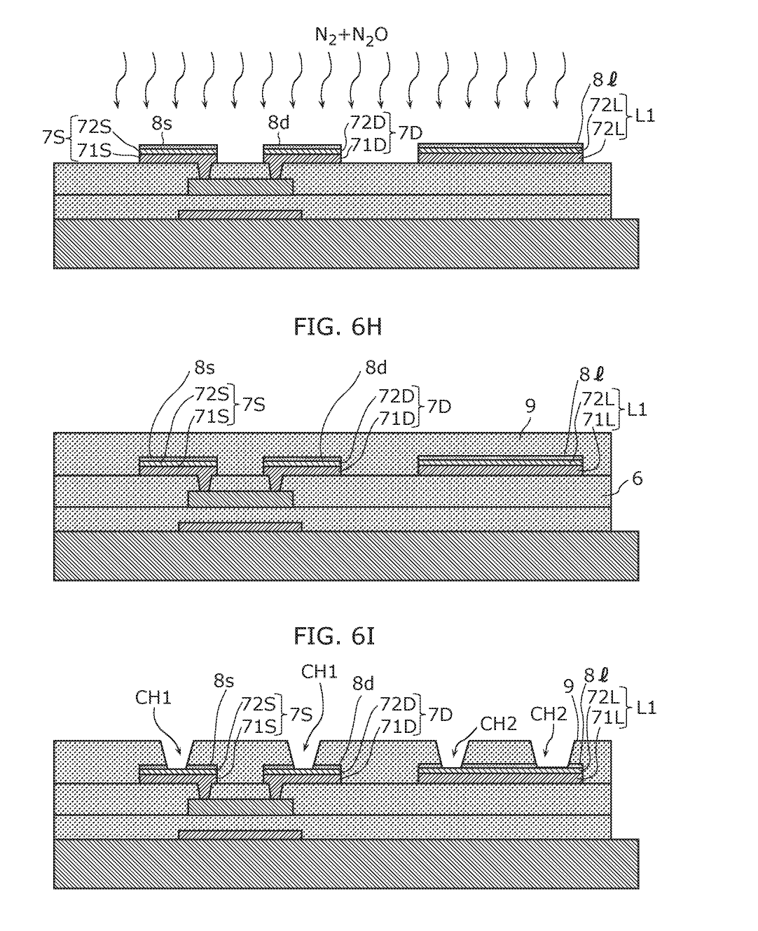

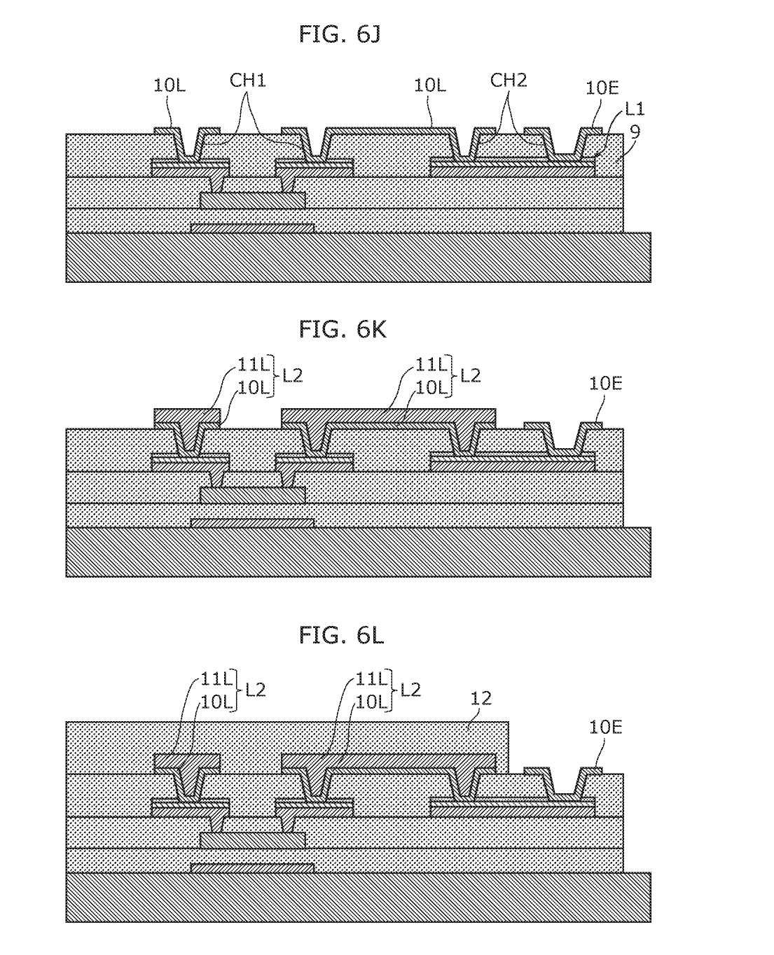

Next, a method for fabricating the TFT substrate 1 according to Embodiment 1 is described, with reference to FIGS. 6A through 6L. FIGS. 6A through 6L are cross-sectional views illustrating steps in the method for fabricating the thin-film transistor substrate according to Embodiment 1.

First, as illustrated in FIG. 6A, the substrate 2 is prepared, and the gate electrode 3 is formed in the predetermined shape above the substrate 2. For example, the gate electrode 3 is formed in the predetermined shape by depositing a metal gate film on the substrate 2 by sputtering technique, and processing the metal gate film by photolithography and wet etching.

Next, as illustrated in FIG. 6B, the gate insulating film 4 is formed above the substrate 2. For example, the gate insulating film 4 comprising silicon oxide is deposited by, for example, plasma CVD, covering the gate electrode 3.

Next, as illustrated in FIG. 6C, the oxide semiconductor layer 5 is formed in the predetermined shape above the substrate 2. For example, the oxide semiconductor layer 5 is formed in the predetermined shape by, for example, depositing an InGaZnO_{X} transparent amorphous oxide semiconductor on the gate insulating film 4 by a sputtering technique, and processing the transparent amorphous oxide semiconductor by photolithography and etching.

Next, as illustrated in FIG. 6D, the insulating layer 6 is formed on the gate insulating film 4, covering the oxide semiconductor layer 5. For example, the insulating layer 6 comprising silicon oxide is deposited by plasma CVD.

Then, as illustrated in the figure, the contact holes for bringing the oxide semiconductor layer 5 into contact with the source electrode 7S and the drain electrode 7D are formed by etching away the portions of the insulating layer 6. For example, the contact holes are formed in the insulating layer 6 by photolithography and etching, in a manner that portions of the oxide semiconductor layer 5 are exposed.

Next, as illustrated in FIGS. 6E and 6F, the source electrode 7S, the drain electrode 7D, and the bottom layer interconnection L1 are formed in the predetermined shapes as electrodes connected to the oxide semiconductor layer 5.

In this case, first, as illustrated in FIG. 6E, a metallic laminated film is formed on the oxide semiconductor layer 5. For example, a first metal film 71 is formed on the insulating layer 6, filling the contact holes in the insulating layer 6. Next, a second metal film 72 is formed on the first metal film 71. Specifically, the Cu film is deposited as the first metal film 71 by sputtering, and the Cu—Mn alloy film is deposited as the second metal film 72 by sputtering.

Next, as illustrated in FIG. 6F, the source electrode 7S, the drain electrode 7D, and the bottom layer interconnection L1 are formed in predetermined patterns by processing the laminated film which includes the first metal film 71 and the second metal film 72. For example, by processing the laminated film including the first metal film 71 and the second metal film 72 by photolithography and etching, the source electrode 7S, the drain electrode 7D, and the bottom layer interconnection L1 are formed. The source electrode 7S is a laminated film including the first electrode film 71S and the second electrode film 72S. The drain electrode 7D is a laminated film including the first electrode film 71D and the second electrode film 72D. The bottom layer interconnection L1 is a laminated film including the first interconnect layer 71L and the second interconnect layer 72L.

Next, an oxygen-containing gas is supplied, as illustrated in FIG. 6G. For example, a gas mixture comprising nitrogen (N₂) and nitrous oxide (N₂O) is supplied as the oxygen-containing gas. In this case, the oxygen-containing gas may be supplied with heat treatment of 250 degrees Celsius or below. In the present embodiment, the gas mixture comprising N₂ and N₂O (2%) is supplied for four minutes under a reduced pressure (3 Torr) at 250 degrees Celsius or less. While the present embodiment is described with reference to simply supplying the gas mixture, plasma processing using the above gas mixture may be carried out.

As shown in the figure, the oxide films 8s and 8d are formed on the respective surfaces of the source electrode 7S and the drain electrode 7D by supplying the oxygen-containing gas to the source electrode 75, the drain electrode 7D, and the bottom layer interconnection L1 as such. Specifically, the oxide films 8s and 8d are formed by oxidization of the respective surfaces of the second electrode films 72S and 72D which are the Cu—Mn alloy films, at which time the oxide film 8l is formed on the surface of the bottom layer interconnection L1 as well. Specifically, the oxide film 8l is formed by oxidization of the surface of the second interconnect layer 72L which is the Cu—Mn alloy film.

Next, as illustrated in FIG. 6H, the first protective film 9 is formed on the insulating layer 6, covering the source electrode 75 and the drain electrode 7D as well as the oxide films 8s and 8d. At this time, the first protective film 9 is formed covering the bottom layer interconnection L1 as well as the oxide film 8l formed on the surface of the bottom layer interconnection L1. For example, the first protective film 9 comprising silicon oxide is deposited by plasma CVD at a deposition temperature of 300 degrees Celsius.

Next, as illustrated in FIG. 6I, the portions of the first protective film 9 and the portions of the oxide films 8s and 8d are etched away so that the source electrode 7S and the drain electrode 7D are exposed. The portions of the first protective film 9 and the portions of the oxide films 8s and 8d that are above the source electrode 7S and the drain electrode 7D are removed by photolithography and etching, for example, to form the first contact hole CH1 extending through the first protective film 9 and the oxide film 8s and the first contact hole CH1 extending through the first protective film 9 and the oxide film 8d.

At this time, another portion of the first protective film 9 and a portion of the oxide film 8l are removed by the above etching at the same time when etching away the portions of the first protective film 9 and the oxide films 8s and 8d, so that the bottom layer interconnection L1 is also exposed as illustrated in the figure. For example, the portion of the first protective film 9 and the portion of the oxide film 8l that are above the bottom layer interconnection L1 are removed at the same time when the above photolithography and etching technique are performed, to form the second contact holes CH2 extending through the first protective film 9 and the oxide film 81.

In the present embodiment, the portions of the first protective film 9 and the portions of the oxide films 8s, 8d, and 8l are removed by dry etching for forming the first contact holes CH1 and the second contact holes CH2. The etching gas may be CF₄, for example. It should be noted that depending on etchant, the portions of the first protective film 9 and the portions of the oxide films 8s, 8d, and 8l can be removed by wet etching, rather than by dry etching.

Next, as illustrated in FIG. 6J, the first interconnect layer 10L is formed in a predetermined shape as the first conductor film connected to the exposed source electrode 7S and drain electrode 7D. At this time, as illustrated in the figure, at the same time when the first interconnect layer 10L (the first conductor film) is formed, the extraction terminal electrode 10E is formed in a predetermined shape as the second conductor film connected to an exposed portion of the bottom layer interconnection L1.

In this case, first, a conductor film comprising, for example, the ITO film, is deposited by sputtering along the surfaces of the first contact holes CH1 and the surface of the first protective film 9, covering the exposed source electrode 7S and drain electrode 7D.

Then, the first interconnect layer 10L and the extraction terminal electrode 10E are formed in predetermined patterns by processing the conductor film by photolithography and wet etching. It should be noted that, after this, the resistance of the patterned first interconnect layer 10L and the patterned extraction terminal electrode 10E may be reduced by heat annealing.

Next, as illustrated in FIG. 6K, the second interconnect layer 11L is formed on the first interconnect layer 10L (the first conductor film). For example, the Cu film is formed in a predetermined shape on the first interconnect layer 10L. This forms the top layer interconnection L2 made of a laminated film including the first interconnect layer 10L and the second interconnect layer 11L. It should be noted that the Cu film is not formed on the extraction terminal electrode 10E.

Next, as illustrated in FIG. 6L, the second protective film 12 is formed in a predetermined region on the first protective film 9, covering the top layer interconnection L2. It should be noted that the second protective film 12 is not formed on the extraction terminal electrode 10E.

### Advantageous Effects

In the following, advantageous effects obtained by the TFT substrate 1 according to Embodiment 1 are described, including a process by which the technology according to the present disclosure has been achieved

In recent years, upsizing and increased resolution of screens of display devices are demanded, and as a semiconductor layer (the channel layer) of a thin film transistor included in the display devices, the use of an oxide semiconductor having high carrier mobility, such as IGZO, is considered. The thin film transistor using the oxide semiconductor needs silicon oxide as a protective film for ensuring reliability.

In addition, the upsizing and increased resolution of screens of display devices tend to increase a length and reduces a thickness of interconnection. Due to this, interconnect resistance increases, ending up degrading quality of a displayed image. Particularly in a thin film transistor, a source electrode and a drain electrode may be formed in the same layer, and thus materials and structures of the source electrode and the drain electrode are required to yield performances not only as a thin film transistor but also as an interconnection. Thus, in order to achieve a low-resistance interconnection, the use of Cu as the materials of the source electrode and the drain electrode is considered.

In this case, if an oxide film such as a silicon oxide film is formed as a protective film on the interconnection, the source electrode, and the drain electrode which are formed using Cu, there arises a problem that Cu included in the interconnection, the source electrode, and the drain electrode is oxidized by oxygen used in depositing the oxide film. There is another problem that a desired transistor property cannot be obtained if Cu diffuses.

Thus, to prevent the oxidization of Cu and the diffusion of Cu, forming a Cu—Mn alloy film, as a cap layer, on the Cu film is considered.

However, it is found that once the Cu—Mn alloy film is actually formed on the Cu film, a highly resistive altered layer is thereafter formed on the surface of CuMn alloy film when depositing the oxide film, such as silicon oxide, as the protective film. In addition, it is found that the altered layer cannot be removed by the dry etching for forming the contact holes in the protective film, ending up increasing the contact resistance between the source electrode and the drain electrode and between the bottom layer interconnection (the bottom electrode) and the top layer interconnection (the top electrode) in the same layer as the source electrode and the drain electrode. Consequently, poor contact results.

According to a study conducted by the inventors, the altered layer is contemplated to be a layer (Mn—Si—Oₓ) where manganese, silicon, and oxygen are bonded.

Through intensive studies on such problems, the inventors have found that in the case of forming the Cu—Mn alloy film and then separately forming the oxide film as the protective film, the development of the altered layer can be suppressed by forming, prior to forming the protective film, a surface oxide film on the Cu—Mn alloy film by a process of facilitating oxidization of the Cu—Mn alloy film.

The technology according to the present disclosure is based on such conception, where the oxide film of the Cu—Mn alloy film is deliberately formed on the surface of the Cu—Mn alloy film after which the protective film is formed, and then the Cu—Mn alloy film is exposed by simultaneously etching away a portion of the protective film and a portion of the oxide film.

Specifically, the method for fabricating the TFT substrate 1 according to the present embodiment includes: forming a predetermined electrode (the source electrode 7S and the drain electrode 7D, or the bottom layer interconnection L1), forming an oxide film (the oxide films 8s and 8d, or the oxide film 8l) on a surface of the predetermined electrode by supplying an oxygen-containing gas; forming, after the oxide film is formed, the first protective film 9 covering the oxide film; etching away a portion of the first protective film 9 and a portion of the oxide film to expose the predetermined electrode; and forming a conductor film (the first interconnect layer 10L, or the extraction terminal electrode 10E) connected to the exposed, predetermined electrodes, wherein forming the predetermined electrode includes forming a Cu film (the first electrode films 71S and 71D, or the first interconnect layer 71L) and forming a Cu—Mn alloy film (the second electrode films 72S and 72D, or the second interconnect layer 72L) on the Cu film.

Previously forming as such the oxide film on the surface of a predetermined electrode configured of a laminated film including the Cu film and the Cu—Mn alloy film prevents the altered layer as described above from being formed on the surface of the predetermined electrode when forming the first protective film 9. In addition, the oxide film of the Cu—Mn alloy film deliberately formed on the surface of the predetermined electrode can be removed by the etching for forming the contact holes in the first protective film 9. This can introduce good contact resistance characteristics between the predetermined electrode (the source electrode 7S and the drain electrode 7D, or the bottom layer interconnection L1) and the conductor film (the first interconnect layer 10L, the extraction terminal electrode 10E) which is a top electrode. As a result, a TFT substrate having desired performance is achieved.

### Embodiment 2

Next, Embodiment 2 is described. It should be noted that the configuration of an organic EL display device according to the present embodiment is the same as the configuration of the organic EL display device 100 according to Embodiment 1, and thus will not be described. A TFT substrate is described.

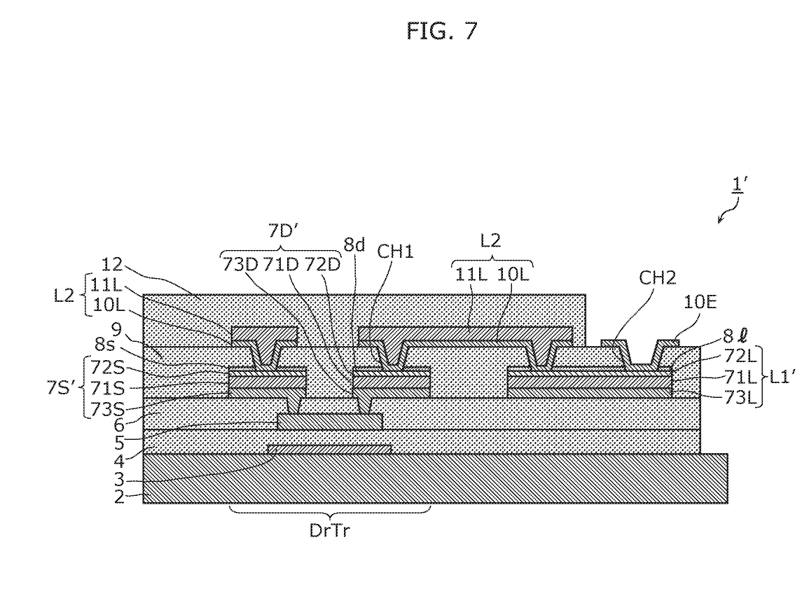

FIG. 7 is a schematic sectional view of the TFT substrate according to Embodiment 2.

The TFT substrate 1 according to Embodiment 1 includes the source electrode 7S, the drain electrode 7D, and the bottom layer interconnection L1 each having a two-layer structure. In contrast, a TFT substrate 1′ according to the present embodiment includes a source electrode 7S′, a drain electrode 7D′, and a bottom layer interconnection L1 each having a three-layer structure, as shown in FIG. 7. The other configuration is the same as Embodiment 1.

Specifically, a third electrode film 73S is added, as the lowermost layer, to the source electrode 7S′. The source electrode 7S′ includes three layers of the third electrode film 73S, the first electrode film 71S, and the second electrode film 72S stacked in the listed order. Likewise, a third electrode film 73D is added, as the lowermost layer, to the drain electrode 7D′. The drain electrode 7D′ includes three layers of the third electrode film 73D, the first electrode film 71D, and the second electrode film 72D stacked in the listed order. A third interconnect layer 73L is added, as the lowermost layer, to the bottom layer interconnection L1′. The bottom layer interconnection L1′ includes three layers of the third interconnect layer 73L, the first interconnect layer 71L, and the second interconnect layer 72L stacked in the listed order.

The third electrode film 73S, the third electrode film 73D, and the third interconnect layer 73L, which are added as the respective lowermost layers, are layers adhesive to underlying layers, and formed on the oxide semiconductor layer 5 and the insulating layer 6. Furthermore, the third electrode film 73S, the third electrode film 73D, and the third interconnect layer 73L also serve as Cu diffusion prevention layers which suppress the diffusion, through the oxide semiconductor layer 5, of Cu atoms included in the first electrode film 71S, the first electrode film 71D, and the first interconnect layer 71L which are formed of Cu.

The first electrode film 71S, the first electrode film 71D, and the first interconnect layer 71L are intermediate layers serving as primary electrode layers (primary interconnect layers) comprising Cu as a principal component. The first electrode film 71S, the first electrode film 71D, and the first interconnect layer 71L are formed between a bottom layer and a top layer, that is, between the third electrode film 73S and the second electrode film 72S, between the third electrode film 73D and the second electrode film 72D, and between the third interconnect layer 73L and the second interconnect layer 72L, respectively. The use of Cu as a major material of the intermediate layers can reduce the resistance of the interconnections and the electrodes.

The second electrode film 72S, the second electrode film 72D, and the second interconnect layer 72L are top layers serving as cap layers for protecting the first electrode film 71S, the first electrode film 71D, and the first interconnect layer 71L, respectively. The second electrode film 72S, the second electrode film 72D, and the second interconnect layer 72L are formed on the first electrode film 71S, the first electrode film 71D, and the first interconnect layer 71L, respectively.

Specifically, the source electrode 7S′, the drain electrode 7D′, and the bottom layer interconnection L1 may each be a laminated film (the Cu—Mn alloy film/the Cu film/the Mo film) in which an Mo film, the Cu film, and the Cu—Mn alloy film are stacked in the listed order, or a laminated film (the Cu—Mn alloy film/the Cu film/the Cu—Mn alloy film) in which the Cu—Mn alloy film, the Cu film, and the Cu—Mn alloy film are stacked in the listed order.

Adding the Mo film or the Cu—Mn alloy film as such as the lowermost layer (the third electrode film 73S, the third electrode film 73D, and the third interconnect layer 73L) can suppress the diffusion of Cu atoms included in the intermediate layer (the first electrode film 71S, the first electrode film 71D, and the third interconnect layer 73L) through the oxide semiconductor layer 5. Furthermore, forming the Mo film or the Cu—Mn alloy film as the lowermost layer achieves the enhancement in adhesion of the lowermost layer to the underlying layers (the oxide semiconductor layer 5, the insulating layer 6).

Moreover, forming the Cu—Mn alloy film as the uppermost layer (the second electrode film 72S, the second electrode film 72D, and the second interconnect layer 72L) can suppresses the alteration of the intermediate layer due to the oxidization of Cu atoms in the intermediate layer. This can suppress an increase in resistance of the interconnections and the electrodes caused by the Cu oxidization.

It should be noted that the method for fabricating the TFT substrate 1′ according to the present embodiment can be implemented according to the method for fabricating the TFT substrate 1 according to Embodiment 1. In this case, the Mo film or the Cu—Mn alloy film, which is the lowermost layers (the third electrode films 73S, 73D, and the third interconnect layer 73L) of the source electrode 7S′, the drain electrode 7D′, and the bottom layer interconnection L1°, can be deposited by sputtering.

As above, according to the present embodiment, the same advantageous effects as Embodiment 1 are obtained.

Moreover, in the present embodiment, as with Embodiment 1, by supplying the oxygen-containing gas with heat treatment of 250 degrees Celsius or less, the oxide films 8s, 8d, and 8l are formed on the surfaces of the Cu—Mn alloy films (the second electrode films 72S and 72D, and the second interconnect layer 72L) included in the source electrode 7S′, the drain electrode 7D′, and the bottom layer interconnection LV, respectively. In this case, in the present embodiment, the Mo film (the third electrode films 73S and 73D, and the third interconnect layer 73L) is formed as a layer adjacent to the oxide semiconductor layer 5. The Mo film does not oxidize in a temperature range of 250 degrees Celsius or less. As a result, no oxide film is formed at an interface between the oxide semiconductor layer 5 and the Mo film at the heat treatment during the supply of the oxygen-containing gas.

### Example

Next, examples are described in which experiments are conducted using different materials and different structures of the electrodes and the interconnections included in the TFT substrate. It should be noted that when the electrodes and the interconnections are each configured in a two-layer structure, the TFT substrate 1 according to Embodiment 1 described above is used, and when the electrodes and the interconnections are each configured in a three-layer structure, the TFT substrate 1′ according to the above Embodiment 2 described above is used.

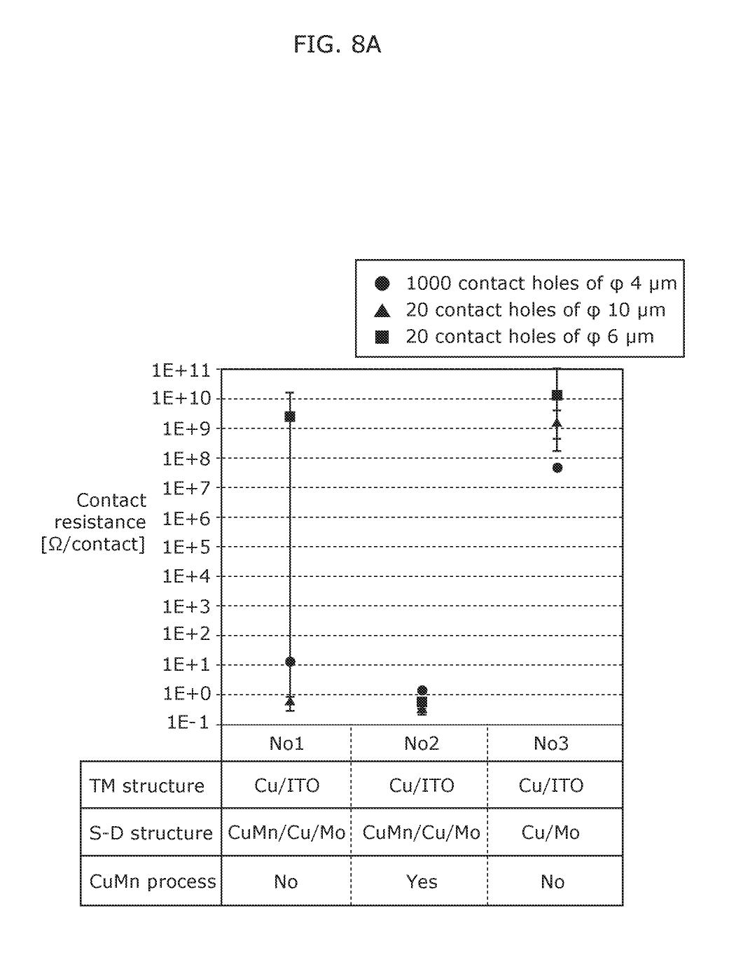

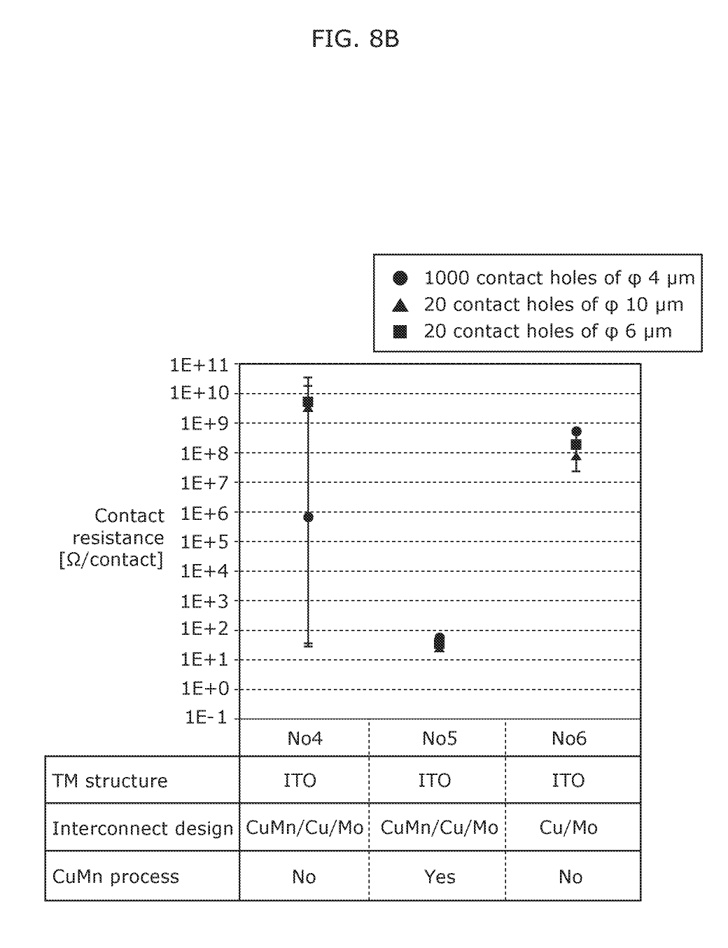

First, contact resistance at contact portion in the TFT substrate is described, with reference to FIGS. 8A and 8B.

FIG. 8A is a diagram showing contact resistance of three kinds of samples, No1, No2, and No3 in a first contact hole CH1 (the drain electrode, the source electrode, and the top layer interconnection). FIG. 8B is a diagram showing contact resistance of three kinds of samples, No4, No5, and No6 in a second contact holes CH2 (the bottom layer interconnection and an extraction electrode).

In FIGS. 8A and 8B, “TM structure” indicates film structures of the top layer interconnection and the extraction electrode which are top electrodes (TM).

As shown in FIG. 8A, “TM structure” of the sample No1, “TM structure” of the sample No2, and “TM structure” of the sample No3 are a two-layer structure in which the first interconnect layer 10L is the ITO film and the second interconnect layer 11L is the Cu film. As shown in FIG. 8B, “TM structure” of the sample No4, “TM structure” of the sample No5, and “TM structure” of the sample No6 are a monolayer structure in which the extraction terminal electrode 10E is the ITO film.

Also in FIG. 8A, “S-D structure” indicates film structures of one of the source electrode and the drain electrode which are bottom electrodes. In FIG. 8B, “Interconnect design” indicates the film structure of the bottom layer interconnection which is the bottom electrode.

As shown in FIGS. 8A and 8B, “S-D structure” of the sample No1, “S-D structure” of the sample No2, “Interconnect design” of the sample No4, and “Interconnect design” of the sample No5 are a three-layer structure in which the third electrode film 73D (the lowermost layer) is the Mo film, the first electrode film 71D (the intermediate layer) is the Cu film, and the second electrode film 72D (the uppermost layer) is a Cu—Mn film. On the other hand, “S-D structure” of the sample Not and “Interconnect design” of the sample No6 are a two-layer structure in which the first electrode film 71D (the bottom layer) is the Mo film, and the second electrode film 72D (the top layer) is the Cu film.

Also in FIGS. 8A and 8B, “CuMn process” indicates a process in which the Cu—Mn film is formed, after which the oxygen-containing gas is supplied. As shown in FIGS. 8A and 8B, the samples No1, No3, No4, and No6 have not undergone “CuMn process.” The samples Not and No5, on the other hand, have undergone “CuMn process,” and the oxide films 8d and 8l are formed on the surfaces of the respective Cu—Mn films.

It should be noted that in FIGS. 8A and 8B, circles (closed circles) indicate results obtained by forming 1000 first contact holes CH1 (the second contact holes CH2) having a pore size of 4 μm, triangles (closed triangles) indicate results obtained by forming 20 first contact holes CH1 (the second contact holes CH2) having a pore size of 10 μm, squares (closed squares) indicate results obtained by forming 20 first contact holes CH1 (the second contact holes CH2) having a pore size of 6 μm, any one of which indicate an average value.

Compare the sample No1 and the sample Not that have the same film structure. As a result, it can be seen, as shown in FIG. 8A, that the sample No2 having undergone “CuMn process,” has reduced variation in contact resistance, as compared to the sample No1 which has not undergone “CuMn process.”

Likewise, compare the sample No4 and the sample No5 that have the same film structure. It can be seen, as shown in FIG. 8B, that the sample No5 having undergone “CuMn process” has reduced variation in contact resistance, as compared to the sample No4 which has not undergone “CuMn process”.

In addition, it can be seen, as shown in FIG. 8A, that contact resistance is increased in the sample No3 in which the Cu—Mn film is not formed as the cap layer on the source electrode or the drain electrode and which has not undergone “CuMn process.” In contrast, it can be seen that contact resistance is reduced in the sample No2 in which the Cu—Mn film is formed as the cap layer on the source electrode or the drain electrode, and which has undergone “CuMn process.” It should be noted, as shown in FIG. 8A, that the CuMn process achieves the reduction of the contact resistance of the source electrode and the drain electrode to 10 (Ω/□) or less.

Likewise, it can be seen, as shown in FIG. 8B, that contact resistance is increased in the sample No6 in which the Cu—Mn film is not formed as the cap layer on the bottom layer interconnection and which has not undergone “CuMn process.” In contrast, it can be seen that contact resistance is reduced in the sample No5 in which the Cu—Mn film is formed as the cap layer on the bottom layer interconnection and which has undergone “CuMn process.” It should be noted, as shown in FIG. 8B, that the CuMn process achieves the reduction of the contact resistance of the interconnections to 10² (Ω/□) or less.

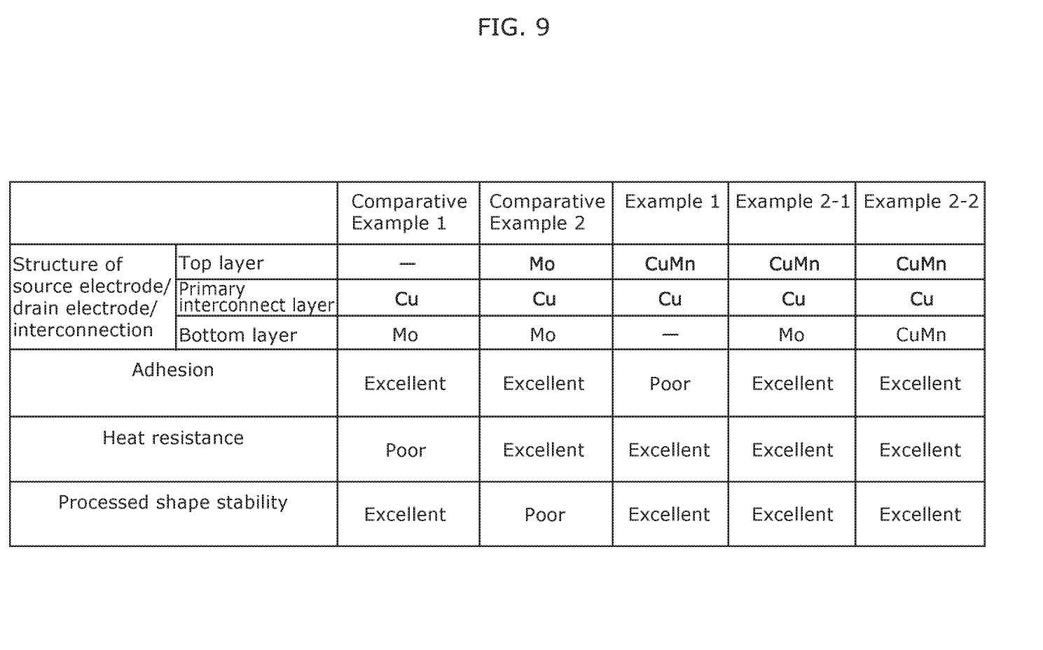

Next, the inventors have intensively studied on film structures and film materials that are suitable for the source electrode, the drain electrode, and the bottom layer interconnection when Cu having low resistivity is used as a main interconnect material. FIG. 9 indicates the result, showing a table indicating characteristics of the source electrode, the drain electrode, and the bottom layer interconnection, depending on a film structure and a film material.

FIG. 9 shows five examples of the source electrode, the drain electrode, and the bottom layer interconnection which have the Cu film as their primary interconnect layer. In FIG. 9, adhesion indicates an assessment as to whether the source electrode, the drain electrode, and the bottom layer interconnection are normally adhered to their underlying layer (an oxide semiconductor layer, a gate insulating film). Heat resistance indicates an assessment as to whether the source electrode, the drain electrode, and the bottom layer interconnection can withstand a temperature (e.g., up to 300 degrees Celsius) in the heat treatment step or the oxidation processing step during the process of fabricating the TFT substrate (particularly, heat resistance in oxidizing atmosphere). Processed shape stability indicates an assessment as to whether the source electrode, drain electrode, and bottom layer interconnection after the processing have normal shapes, or whether predetermined processing can be applied to the source electrode, the drain electrode, and the bottom layer interconnection in patterning them. An assessment as being Excellent indicates that there was no problem and assessment as being Poor indicates that there was some problem.

Comparative Example 1 employs a two-layer structure configured of the Mo film (the bottom layer) and the Cu film (the primary interconnect layer), where the Mo film is formed below the Cu film to enhance adhesion to an oxide semiconductor layer. In this case, there was no problem with respect to the adhesion and the processed shape stability, but there was with respect to the heat resistance.

Comparative Example 2 employs a three-layer structure configured of the Mo film (the bottom layer), the Cu film (the primary interconnect layer), and the Mo film (the top layer), where the Mo film is formed as the bottom layer to enhance adhesion of the bottom layer to an oxide semiconductor layer. It was found that, in this case, compared to Comparative Example 1, there was a problem with processed shape stability even though the problem with the heat resistance was resolved. It is contemplated that cell reaction caused by the Mo films has lead to a processed shape defect.

Example 1 employs a two-layer structure configured of the Cu film (the primary interconnect layer) and the Cu—Mn alloy film (the top layer), where a cap layer comprising the Cu—Mn alloy film is formed on the Cu film. Forming the cap layer comprising the Cu—Mn alloy film as such achieves a film structure which has excellent heat resistance and excellent processed shape stability. However, it was found that Cu has a problem with adhesion in that Cu hardly adheres to the oxide semiconductor layer.

Example 2-1 employs a three-layer structure configured of the Mo film (the bottom layer), the Cu film (the primary interconnect layer), and the Cu—Mn alloy film (the top layer), where the Mo film employed in Comparative Example 2 as the top layer is changed to the Cu—Mn alloy film. According to this configuration, a film structure that has excellent adhesion, excellent heat resistance, and excellent processed shape stability is obtained. In other words, in Example 2-1, cell reaction as seen in Comparative Example 2 did not take place, causing no defect in processed shape stability.

Example 2-2 employs a three-layer structure configured of the Cu—Mn alloy film (the bottom layer), the Cu film (the primary interconnect layer), and the Cu—Mn alloy film (the top layer), where the Mo films employed in Comparative Example 2 as the top layer and the bottom layer are changed to the Cu—Mn alloy films. According to this configuration, a film structure that has excellent adhesion, excellent heat resistance, and excellent processed shape stability is obtained. In Example 2-2 also, no cell reaction took place, causing no defect in processed shape stability.

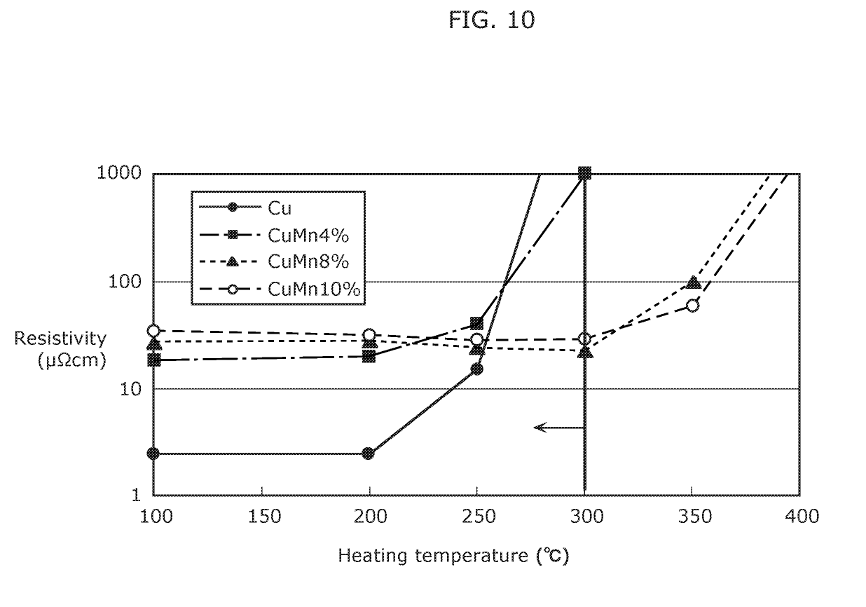

Next, the results of an experiment conducted with respect to a Mn concentration of the Cu—Mn alloy film are described, with reference to FIG. 10. In the experiment, a plurality of monolayer films of the Cu—Mn alloy film having different Mn concentrations are fabricated and examined for changes in resistivity for each Cu—Mn alloy film when heated.

Specifically, as shown in FIG. 10, respective resistivity values of four different CuMn monolayer films having an Mn concentration of 0% (Cu), an Mn concentration of 4% (CuMn of 4%), an Mn concentration of 8% (CuMn of 8%), and a Cu concentration of 10% (CuMn of 10%) were each measured when the heating temperature was 100 degrees Celsius, 200 degrees Celsius, 250 degrees Celsius, 300 degrees Celsius, and 350 degrees Celsius.

Here, the Cu—Mn alloy film is required to have heat resistance of 300 degrees Celsius, due to the upper limit of a process temperature in the TFT processing performed after the interconnection is formed. For example, when depositing silicon oxide by plasma CVD to form the protective film 26, a deposition temperature for forming the protective film 26 is 300 degrees Celsius maximum. From this, preferably, the Cu—Mn alloy film has stable resistivity at 300 degrees Celsius or less.

It can be seen, as shown in FIG. 10, that when the Mn concentrations of the Cu—Mn alloy film is 0% and 4%, the resistivity rapidly increases as the heating temperature exceeds 250 degrees Celsius. This is contemplated to be an increase of the resistivity due to oxidization of the Cu—Mn alloy film.

On the other hand, when the Mn concentrations of the Cu—Mn alloy film is at least 8% and 10%, variation in resistivity is not seen at a heating temperature of 300 degrees Celsius or less. In other words, setting the Mn concentration of the Cu—Mn alloy film to at least 8% or greater can ensure the heat resistance that can withstand the upper limit temperature in the TFT processing.

From the above, preferably, the Cu—Mn alloy film has a Mn concentration of 8% or greater. It should be noted that practically, the Cu—Mn alloy film, preferably, has a Mn concentration of 15% or less from the standpoint of an upper limit of a size of a target that can be fabricated.

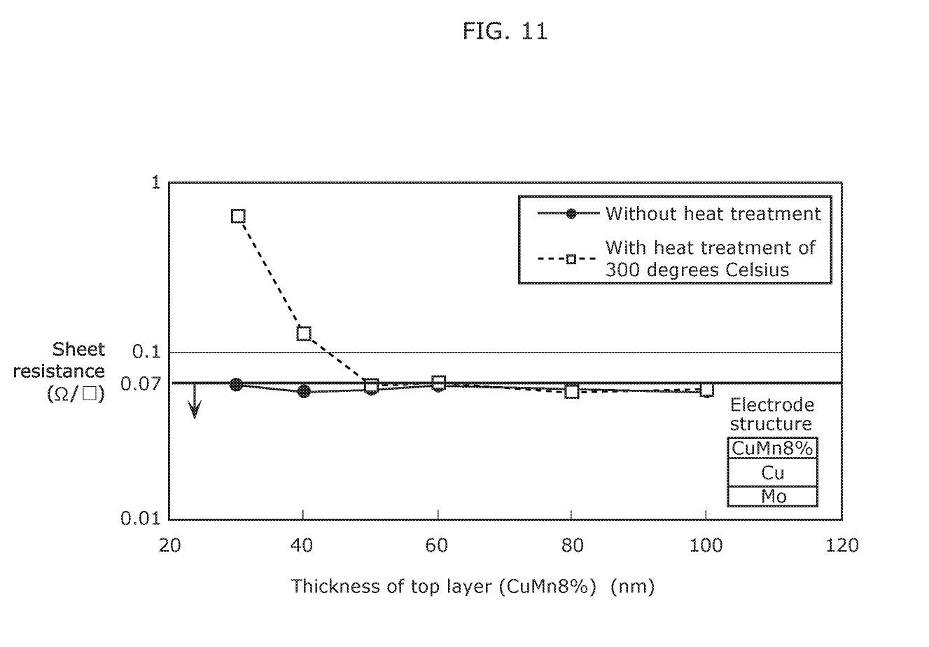

Next, the results of an experiment conducted with respect to the thickness of the Cu—Mn alloy film are described, with reference to FIG. 11. In the experiment, the source electrode and the drain electrode which have a three-layer structure configured of the Mo film (the bottom layer), the Cu film (the intermediate layer), and the Cu—Mn alloy film (the top layer) were examined for changes in sheet resistance with and without the heat treatment, using different thicknesses of the Cu—Mn alloy film which is the cap layer.

Specifically, as shown in FIG. 11, the Cu—Mn alloy film which has the Mn concentration of 8% and thicknesses of 30 nm, 40 nm, 50 nm, 60 nm, 80 nm, and 100 nm were measured for the respective resistivity values with and without the heat treatment of 300 degrees Celsius.

As shown in FIG. 11, it can be seen that when the Cu—Mn alloy film having a thin thickness is heated at the upper limit (300 degrees Celsius) of the process temperature in the TFT processing performed after the interconnection is formed, the resistivity increases. Here, since the display device is required to have an interconnect resistivity of 0.07 (Ω/□) or less, preferably, the Cu—Mn alloy film has a thickness of 50 nm or greater, as shown in FIG. 11, to ensure heat resistance.

It should be noted that preferably, the Cu—Mn alloy film has a thickness of 100 nm or less, from the standpoint of wet etching processing precision.

Moreover, regarding a thickness of the bottom layer in the case of the Cu—Mn alloy film, the Cu—Mn alloy film may have a thickness of 20 nm or greater and 60 nm or less, and in the case of the Mo film, the Mo film may have a thickness of 10 nm or greater and 40 nm or less. Having the film thickness within this range allows a desired transistor property to be attained.

Moreover, since the interconnect resistivity is required to be 0.07 (Ω/□) or less as described above, the intermediate layer which is the Cu film may have a thickness of 300 nm or greater.

### [Variations]

While the thin-film transistor substrate, the method for fabricating the same, and the organic EL display device have been described with reference to the embodiment, the present invention is not limited to the above embodiment.

While the thin film transistor is a bottom-gate TFT in the above embodiment, the thin film transistor may be a top-gate TFT, for example.

Moreover, while in the above embodiment, the thin film transistor is a channel-etching stopper (a channel protective) TFT, the thin film transistor may be a channel etching TFT. In other words, the insulating layer 6 may not be formed in the above embodiment.

Moreover, while in the above embodiment the organic EL display device has been described as a display device which includes the thin-film transistor substrate, the thin-film transistor substrate according to the above embodiment is also applicable to any other display device which includes an active matrix substrate, such as liquid crystal display devices, for example.

Moreover, display devices (display panels) such as the organic EL display device described above are useful as flat panel displays, and applicable to any electronic devices that have display panels, such as television sets, personal computers, and mobile phones. The present invention is suitable, particularly, for display devices having large, high-resolution screens.

In other instances, various modifications to the embodiments and variations thereof according to the present invention described above that may be conceived by those skilled in the art and embodiments implemented by any combination of the components and functions shown in the embodiments and variations thereof are also included within the scope of the present invention, without departing from the spirit of the present invention.

### INDUSTRIAL APPLICABILITY

The technology disclosed herein is widely applicable to a thin-film transistor substrate using an oxide semiconductor and a method for fabricating the thin-film transistor substrate, and, the thin-film transistor substrate, and display devices such as an organic EL display device using the thin-film transistor substrate.

### REFERENCE SIGNS LIST

1, 1′ TFT substrate
2 substrate
3, G1, G2 gate electrode
4 gate insulating film
5 oxide semiconductor layer
6 insulating layer
7S, 7S′, S1, S2 source electrode
7D, 7D′, D1, D2 drain electrode
8s, 8d, 8l oxide film
9 first protective film
10L, 71L first interconnect layer
10E extraction terminal electrode
11L, 72L second interconnect layer
12 second protective film
71 first metal film
72 second metal film
71S, 71D first electrode film
72S, 72D second electrode film
73S, 73D third electrode film
73L third interconnect layer
100 organic EL display device
110 pixel
110R, 110G, 110B sub-pixel
111 bank
120 pixel circuit
130 organic EL element
131 anode
132 EL layer
133 cathode
140 gate line
150 source line
160 power supply line
SwTr, DrTr thin film transistor
C capacitor
L1, L1′ bottom layer interconnection
L2 top layer interconnection
CH1 first contact hole
CH2 second contact hole

1. A method for fabricating a thin-film transistor substrate, the method comprising:
(a) forming a gate electrode above a substrate;
(b) forming a gate insulating film above the substrate;
(c) forming an oxide semiconductor layer above the substrate;
(d) forming an electrode connected to the oxide semiconductor layer;
(e) forming an oxide film on a surface of the electrode by supplying an oxygen-containing gas;
(f) forming a protective film covering the oxide film, after step (e);
(g) removing a portion of the protective film and a portion of the oxide film by etching, to expose the electrode; and
(h) forming a first conductor film connected to the exposed electrode, wherein
step (d) includes (d-i) forming a Cu film and (d-ii) forming a Cu—Mn alloy film on the Cu film.

2. The method according to claim 1, wherein
in step (d), an interconnection is also formed using a same material as a material of the electrode,
in step (e), the oxide film is also formed on a surface of the interconnection by supplying the oxygen-containing gas,
in step (f), the protective film is formed covering also the oxide film on the surface of the interconnection,
in step (g), a portion of the protective film and a portion of the oxide film on the surface of the interconnection are also removed by the etching, to expose the interconnection, and
in step (h), a second conductor film connected to the exposed interconnection is also formed.

3. The method according to claim 1, wherein
the first conductor film and the second conductor film are ITO films.

4. The method according to claim 1, further comprising
(i) forming a Cu film on the first conductor film.

5. The method according to claim 1, wherein
the Cu—Mn alloy film has a Mn concentration of 8% or greater.

6. The method according to any of claims 1 to 5 claim 1, wherein
the oxygen-containing gas is a gas mixture comprising N₂ and N₂O.

7. The method according to claim 1, wherein
the oxygen-containing gas is supplied at 250 degrees Celsius or below.

8. The method according to claim 1, wherein
the protective film is a silicon oxide film.

9. The method according to claim 1, wherein
the etching is dry etching.

10. The method according to claim 1, wherein
the oxide semiconductor layer is a transparent amorphous oxide semiconductor.

11. The method according to claim 1, wherein
a contact resistance characteristic of the electrode is 10 (Ω/□) or less.

12. The method according to claim 1, wherein
step (d) further includes forming a Mo film or forming a Cu—Mn film, prior to step (d-i), and
the Cu film is layered on the Mo film or on the Cu—Mn film in step (d-i).

13. The method according to claim 12, wherein
if the electrode is a laminated film including the Mo film, the Cu film, and the Cu—Mn alloy film, the Mo film, as a bottom layer of the electrode, has a thickness of 10 nm or greater and 40 nm or less.

14. The method according to claim 12, wherein
if the electrode is a laminated film including the Cu—Mn alloy film, the Cu film, and the Cu—Mn alloy film, the Cu—Mn alloy film, as a bottom layer of the laminated film, has a thickness of 20 nm or greater and 60 nm or less.

15. A thin-film transistor substrate comprising:
a substrate;
a gate electrode above the substrate;
an oxide semiconductor layer above the substrate;
a gate insulating film between the gate electrode and the oxide semiconductor layer;
an electrode connected to the oxide semiconductor layer;
an oxide film of the electrode, on a surface of the electrode;
a protective film covering the oxide film of the electrode; and
a first conductor film connected to the electrode via a first contact hole extending through the protective film and the oxide film of the electrode, wherein
the electrode is a laminated film including a Cu film and a Cu—Mn alloy film formed on the Cu film.

16. The thin-film transistor substrate according to claim 15, further comprising:
an interconnection in a same layer where the electrode is formed; and
an oxide film of the interconnection, on a surface of the interconnection, wherein
the protective film is covering the oxide film of the interconnection, and
a second conductor film is connected to the interconnection via a second contact hole extending through the protective film and the oxide film of the interconnection.

17. The thin-film transistor substrate according to claim 15, wherein
the first conductor film and the second conductor film are ITO films.

18. The thin-film transistor substrate according to claim 15, wherein
the Cu—Mn alloy film has a Mn concentration of 8% or greater.

19. The thin-film transistor substrate according to claim 15, wherein
the protective film is a silicon oxide film.

20. The thin-film transistor substrate according to claim 15, wherein
the oxide semiconductor layer is a transparent amorphous oxide semiconductor.
